(19) United States
(12) Patent Application Publication
(10) Pub. No.: US 2026/0040570 A1
(43) Pub. Date: Feb. 5, 2026

(54) MEMORY DEVICES INCLUDING CHARGE TRAP MEMORY CELLS AND FERROELECTRIC MEMORY CELLS

(71) Applicant: MICRON TECHNOLOGY, INC., BOISE, ID (US)

(72) Inventors: Richard J. Hill, Boise, ID (US); Pankaj Sharma, Boise, ID (US); Qui V. Nguyen, San Jose, CA (US)

(73) Assignee: MICRON TECHNOLOGY, INC., BOISE, ID (US)

(21) Appl. No.: 19/277,654

(22) Filed: Jul. 23, 2025

Related U.S. Application Data
(60) Provisional application No. 63/677,015, filed on Jul. 30, 2024.

(51) Int. Cl. H10B 51/30; G11C 11/22; G11C 16/08; H10B 43/27; H10B 43/35; H10B 43/40; H10B 51/20; H10B 51/40

(52) U.S. Cl. CPC H10B 51/30; G11C 11/2257; G11C 16/08; H10B 43/27; H10B 43/35; H10B 43/40; H10B 51/20; H10B 51/40

(57) ABSTRACT

A memory device include an array of memory cells and control logic. The array of memory cells includes charge trap memory cells and ferroelectric memory cells. The control logic is configured to access the array of memory cells. The array of memory cells may include a first string of series-connected charge trap memory cells where each charge trap memory cell includes a first gate stack structure. The array of memory cells may include a second string of series-connected ferroelectric memory cells where each ferroelectric memory cell includes a second gate stack structure different from the first gate stack structure.

### RELATED APPLICATION

This application claims the benefit of U.S. Provisional Application No. 63/677,015, filed on Jul. 30, 2025, hereby incorporated herein in its entirety by reference.

### TECHNICAL FIELD

The present disclosure relates generally to memory and, in particular, in one or more embodiments, the present disclosure relates to memory devices including charge trap memory cells and ferroelectric memory cells.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. Each source select transistor may be connected to a source, while each drain select transistor may be connected to a data line, such as column bit line. Variations using more than one select gate between a string of memory cells and the source, and/or between the string of memory cells and the data line, are known.

In programming memory, memory cells might be programmed as what are often termed single-level cells (SLC). SLC may use a single memory cell to represent one digit (e.g., one bit) of data. For example, in SLC, a Vt of 2.5V or higher might indicate a programmed memory cell (e.g., representing a logical 0) while a Vt of-0.5V or lower might indicate an erased memory cell (e.g., representing a logical 1). Such memory might achieve higher levels of storage capacity by including multi-level cells (MLC), triple-level cells (TLC), quad-level cells (QLC), etc., or combinations thereof in which the memory cell has multiple levels that enable more digits of data to be stored in each memory cell. For example, MLC might be configured to store two digits of data per memory cell represented by four Vt ranges, TLC might be configured to store three digits of data per memory cell represented by eight Vt ranges, QLC might be configured to store four digits of data per memory cell represented by sixteen Vt ranges, and so on.

### BRIEF DESCRIPTION OF THE DRAWINGS

FIG. 1 is a simplified block diagram of a memory in communication with a processor as part of an electronic system, according to an embodiment.

FIG. 2A is a schematic of charge trap memory cell portions of an array of memory cells as could be used in a memory of the type described with reference to FIG. 1.

FIG. 2B is a schematic of ferroelectric memory cell portions of an array of memory cells as could be used in a memory of the type described with reference to FIG. 1.

FIGS. 2C-2D are schematics of portions of an array of memory cells as could be used in a memory of the type described with reference to FIG. 1.

FIGS. 3A-3B are cross-sectional views illustrating structures of portions of an array of memory cells according to embodiments.

FIGS. 4A-4D and 4F-4O are cross-sectional views and FIG. 4E is a top view illustrating a method for fabricating a memory array according to embodiments.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments may be utilized and structural, logical and electrical changes may be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting unless otherwise apparent from the context.

Charge trap memory cells (e.g., SLC, TLC, QLC) might have slower read and write speeds compared to ferroelectric memory cells due to the higher bias voltages used to access charge trap memory cells. For example, SLC ferroelectric memory cells might have an about 100 times improvement in speed and a lower power consumption compared to SLC charge trap memory cells due to the lower bias voltages and the thinner physical gate stack of SLC ferroelectric memory cells. Accordingly, disclosed herein are NAND memory devices including memory arrays that cointegrate ferroelectric memory cell blocks with charge trap memory cell (e.g., TLC/QLC) blocks to improve the overall speed of the NAND memory devices. The ferroelectric memory cell blocks may provide an ultrafast cache, such that the disclosed NAND memory devices may close the performance-cost gap between NAND memory and DRAM by providing a high performance cache with a NAND cost structure.

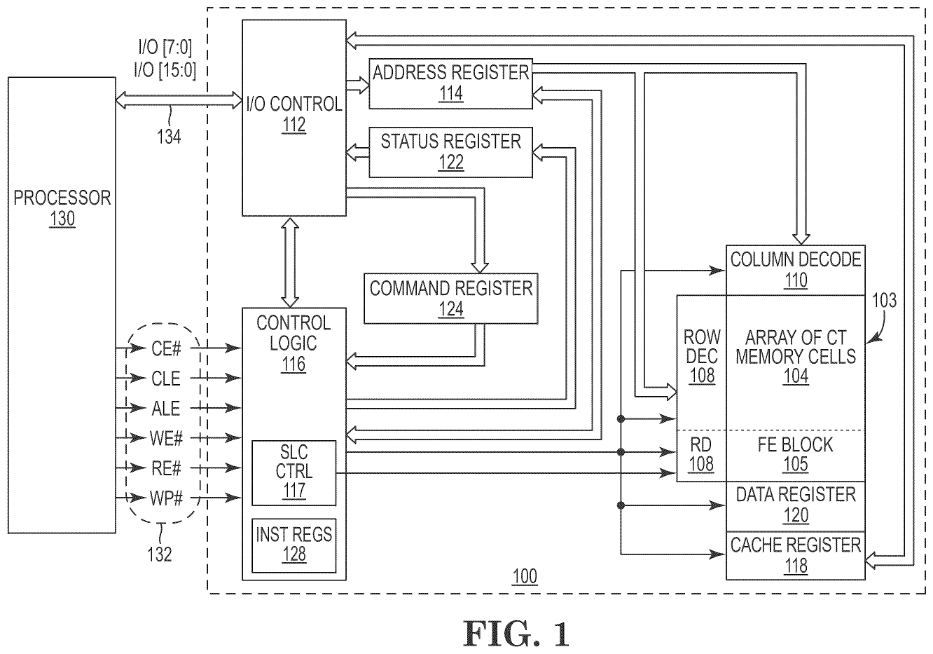

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 103 including an array of charge trap (CT) memory cells 104 and a block (e.g., array) of ferroelectric memory cells 105 that might be logically arranged in rows and columns. The ferroelectric memory cells 105 might comprise between 1 percent and 50 percent of the array of memory cells 103. The ferroelectric memory cells 105 might include a cache block of memory cells for the array of memory cells 103. Charge trap memory cells of a logical row are typically connected to the same access line (commonly referred to as a word line) while charge trap memory cells of a logical column are typically selectively connected to the same data line (commonly referred to as a bit line). A single access line might be associated with more than one logical row of charge trap memory cells and a single data line might be associated with more than one logical column. Charge trap memory cells (not shown in FIG. 1) of at least a portion of array of charge trap memory cells 104 are capable of being programmed to one of at least two target data states. Ferroelectric memory cells of a logical row are typically connected to the same access line while ferroelectric memory cells of a logical column are typically selectively connected to the same data line. A single access line might be associated with more than one logical row of ferroelectric memory cells and a single data line might be associated with more than one logical column. Ferroelectric memory cells (not shown in FIG. 1) of at least a portion of block of ferroelectric memory cells 105 are capable of being programmed to one of two target data states.

A charge trap memory cell row decode circuitry 108, a ferroelectric memory cell row decode circuitry 109, and a column decode circuitry 110 are provided to decode address signals. Address signals are received and decoded to access the array of memory cells 103. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and 109 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 103 in response to the commands and may generate status information for the external processor 130, i.e., control logic 116 is configured to perform access operations (e.g., sensing operations [which might include read operations and verify operations], programming operations and/or erase operations) on the array of memory cells 103. The control logic 116 is in communication with row decode circuitry 108 and 109 and column decode circuitry 110 to control the row decode circuitry 108 and 109 and column decode circuitry 110 in response to the addresses. The control logic 116 might include SLC control logic 117 to control the row decode circuitry 109 in response to the addresses for performing access operations on the block of ferroelectric memory cells 105. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 103.

Control logic 116 might also be in communication with a cache register 118. Cache register 118 latches data, either incoming or outgoing, as directed by control logic 116 to temporarily store data while the array of memory cells 103 is busy writing or reading, respectively, other data. ‘During a programming operation (e.g., write operation), data might be passed from the cache register 118 to the data register 120 for transfer to the array of memory cells 103; then new data might be latched in the cache register 118 from the I/O control circuitry 112. During a read operation, data might be passed from the cache register 118 to the I/O control circuitry 112 for output to the external processor 130; then new data might be passed from the data register 120 to the cache register 118. The cache register 118 and/or the data register 120 might form (e.g., might form a portion of) a page buffer of the memory device 100. A page buffer might further include sensing devices (not shown in FIG. 1) to sense a data state of a memory cell of the array of memory cells 103, e.g., by sensing a state of a data line connected to that memory cell. A status register 122 might be in communication with I/O control circuitry 112 and control logic 116 to latch the status information for output to the processor 130.

Memory device 100 receives control signals at control logic 116 from processor 130 over a control link 132. The control signals might include a chip enable CE#, a command latch enable CLE, an address latch enable ALE, a write enable WE#, a read enable RE#, and a write protect WP#. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 103. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

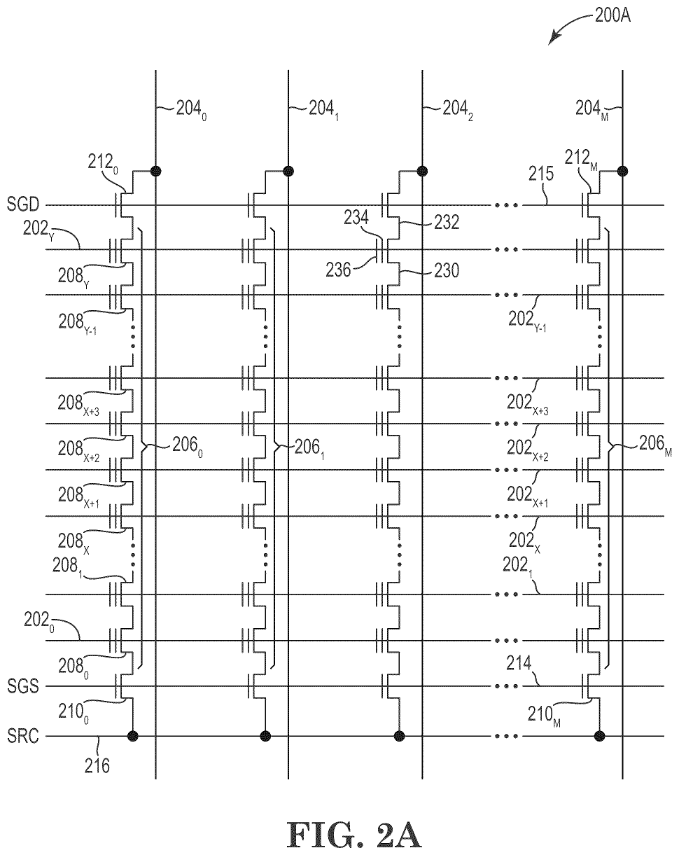

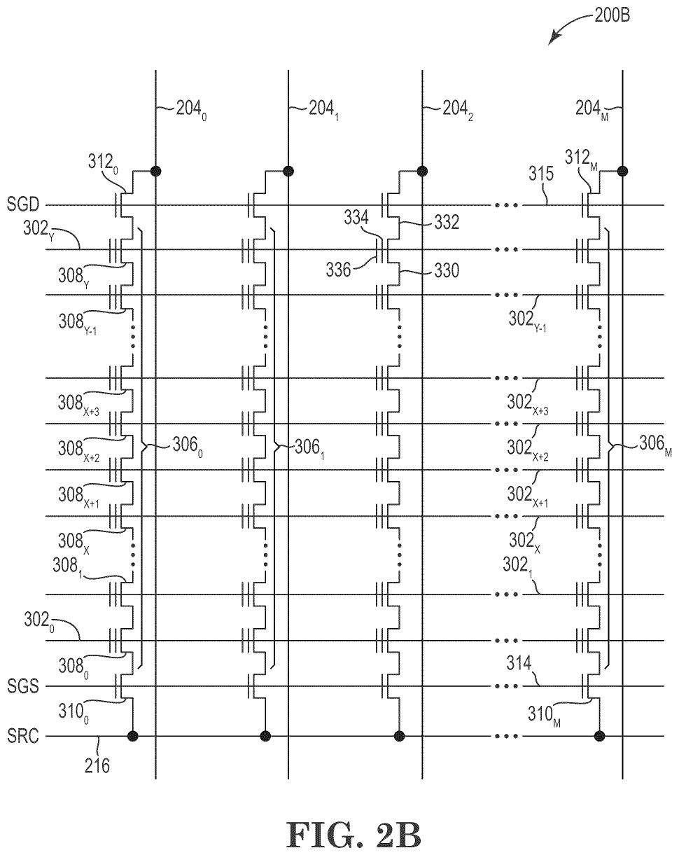

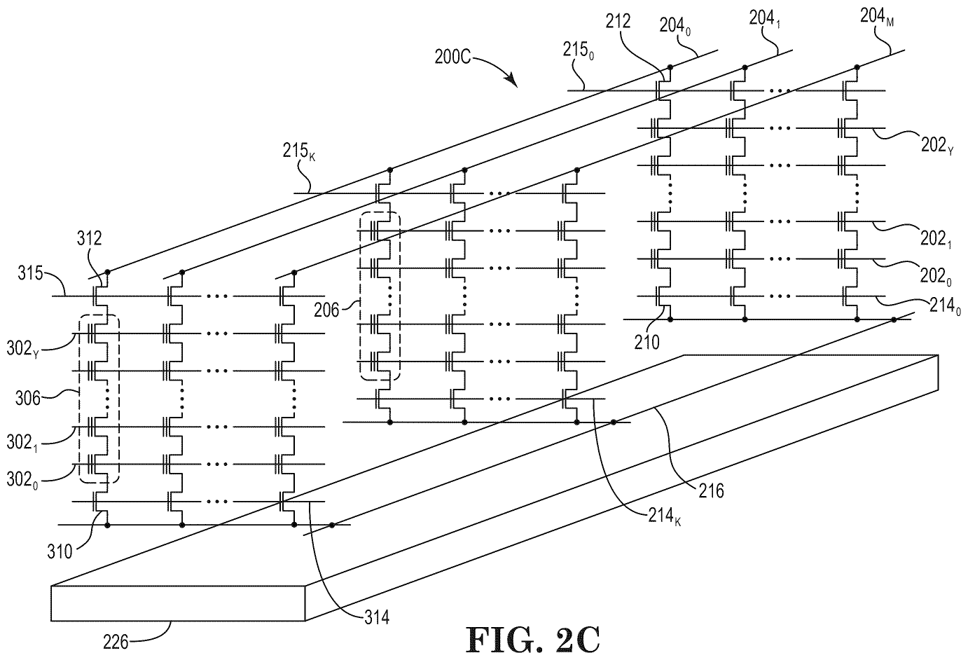

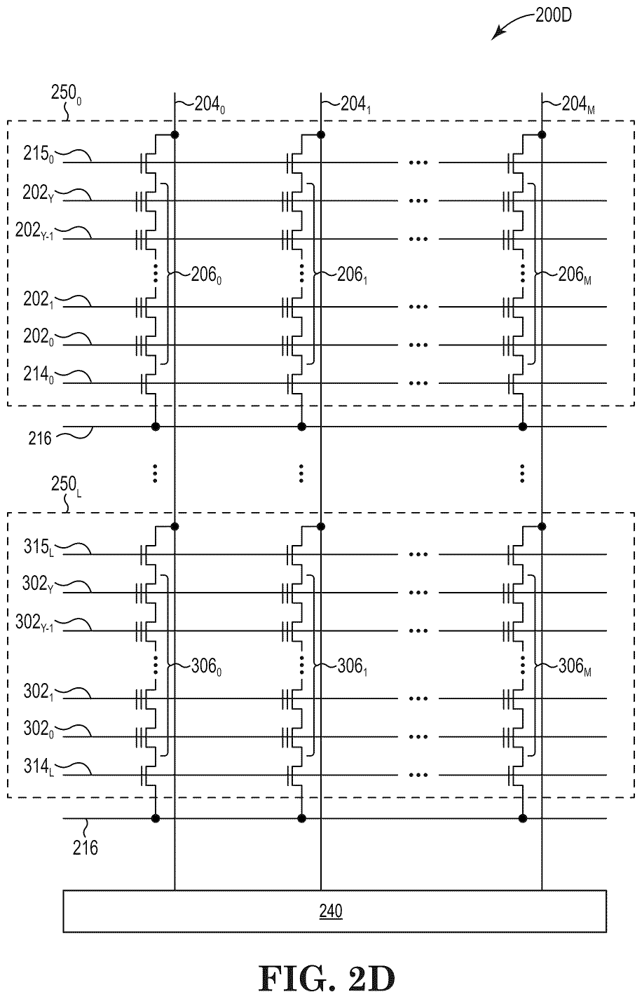

FIG. 2A is a schematic of a portion of an array of charge trap memory cells 200A, as could be used in a memory of the type described with reference to FIG. 1, e.g., as a portion of array of charge trap memory cells 104 of array of memory cells 103. Memory array 200A includes access lines (e.g., word lines) 202₀ to 202_{Y}, and data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{Y}. The memory cells 208 might represent non-volatile memory cells for storage of data. The memory cells 208₀ to 208_{Y} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal.

A source of each select gate 210 might be connected to common source 216. The drain of each select gate 210 might be connected to a memory cell 208₀ of the corresponding NAND string 206. For example, the drain of select gate 210₀ might be connected to memory cell 208₀ of the corresponding NAND string 206₀. Therefore, each select gate 210 might be configured to selectively connect a corresponding NAND string 206 to common source 216. A control gate of each select gate 210 might be connected to select line 214.

The drain of each select gate 212 might be connected to the data line 204 for the corresponding NAND string 206. For example, the drain of select gate 212₀ might be connected to the data line 204₀ for the corresponding NAND string 206₀. The source of each select gate 212 might be connected to a memory cell 208_{Y} of the corresponding NAND string 206. For example, the source of select gate 212₀ might be connected to memory cell 208_{Y} of the corresponding NAND string 206₀. Therefore, each select gate 212 might be configured to selectively connect a corresponding NAND string 206 to the corresponding data line 204. A control gate of each select gate 212 might be connected to select line 215.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{Y} and selectively connected to even data lines 204 (e.g., data lines 204₀, 204₂, 204₄, etc.) might be one physical page of memory cells 208 (e.g., even memory cells) while memory cells 208 commonly connected to access line 202_{Y} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{Y} (e.g., all NAND strings 206 sharing common access lines 202). Unless expressly distinguished, a reference to a page of memory cells herein refers to the memory cells of a logical page of memory cells.

Although the example of FIG. 2A is discussed in conjunction with NAND flash, the embodiments and concepts described herein are not limited to a particular array architecture or structure, and can include other structures (e.g., SONOS or other data storage structure configured to store charge) and other architectures (e.g., AND arrays, NOR arrays, etc.).

FIG. 2B is a schematic of a portion of an array of ferroelectric memory cells 200B, as could be used in a memory of the type described with reference to FIG. 1, e.g., as a portion of block of ferroelectric memory cells 105 of array of memory cells 103. Memory array 200B includes access lines (e.g., word lines) 302₀ to 302_{Y}, and data lines (e.g., bit lines) 204₀ to 204_{M}. The access lines 302 might be connected to global access lines (e.g., global word lines), not shown in FIG. 2B, in a many-to-one relationship. For some embodiments, memory array 200B might be formed over a semiconductor that, for example, might be conductively doped to have a conductivity type, such as a p-type conductivity, e.g., to form a p-well, or an n-type conductivity, e.g., to form an n-well.

Memory array 200B might be arranged in rows (each corresponding to an access line 302) and columns (each corresponding to a data line 204). Each column might include a string of series-connected memory cells (e.g., non-volatile memory cells), such as one of NAND strings 306₀ to 306_{M}. Each NAND string 306 might be connected (e.g., selectively connected) to a common source (SRC) 216 and might include memory cells 308₀ to 308_{Y}. The memory cells 308 might represent non-volatile memory cells for storage of data. The memory cells 308₀ to 308_{Y} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 308 of each NAND string 306 might be connected in series between a select gate 310 (e.g., a field-effect transistor), such as one of the select gates 310₀ to 310_{M} (e.g., that might be source select transistors, commonly referred to as select gate source), and a select gate 312 (e.g., a field-effect transistor), such as one of the select gates 312₀ to 312_{M}(e.g., that might be drain select transistors, commonly referred to as select gate drain). Select gates 310₀ to 310_{M} might be commonly connected to a select line 314, such as a source select line (SGS), and select gates 312₀ to 312_{M} might be commonly connected to a select line 315, such as a drain select line (SGD). Although depicted as traditional field-effect transistors, the select gates 310 and 312 might utilize a structure similar to (e.g., the same as) the memory cells 308. The select gates 310 and 312 might represent a plurality of select gates connected in series, with each select gate in series configured to receive a same or independent control signal.

A source of each select gate 310 might be connected to common source 216. The drain of each select gate 310 might be connected to a memory cell 308₀ of the corresponding NAND string 306. For example, the drain of select gate 310₀ might be connected to memory cell 308₀ of the corresponding NAND string 306₀. Therefore, each select gate 310 might be configured to selectively connect a corresponding NAND string 306 to common source 216. A control gate of each select gate 310 might be connected to select line 314.

The drain of each select gate 312 might be connected to the data line 204 for the corresponding NAND string 306. For example, the drain of select gate 312₀ might be connected to the data line 204₀ for the corresponding NAND string 306₀. The source of each select gate 312 might be connected to a memory cell 308_{Y} of the corresponding NAND string 306. For example, the source of select gate 312₀ might be connected to memory cell 308_{Y} of the corresponding NAND string 306₀. Therefore, each select gate 312 might be configured to selectively connect a corresponding NAND string 306 to the corresponding data line 204. A control gate of each select gate 312 might be connected to select line 315.

The memory array in FIG. 2B might be a quasi-two-dimensional memory array and might have a generally planar structure, e.g., where the common source 216, NAND strings 306 and data lines 204 extend in substantially parallel planes. Alternatively, the memory array in FIG. 2B might be a three-dimensional memory array, e.g., where NAND strings 306 might extend substantially perpendicular to a plane containing the common source 216 and to a plane containing the data lines 204 that might be substantially parallel to the plane containing the common source 216.

Typical construction of memory cells 308 includes a data-storage structure 334 (e.g., a ferroelectric material exhibiting reversible electric polarization) that can determine a data state of the memory cell (e.g., through changes in electric polarization), and a control gate 336, as shown in FIG. 2B. The data-storage structure 334 might include dielectric structures while the control gate 336 is generally formed of one or more conductive materials. In some cases, memory cells 308 might further have a defined source/drain (e.g., source) 330 and a defined source/drain (e.g., drain) 332. Memory cells 308 have their control gates 336 connected to (and in some cases form) an access line 302.

A column of the memory cells 308 might be a NAND string 306 or a plurality of NAND strings 306 selectively connected to a given data line 204. A row of the memory cells 308 might be memory cells 308 commonly connected to a given access line 302. A row of memory cells 308 can, but need not, include all memory cells 308 commonly connected to a given access line 302. Rows of memory cells 308 might often be divided into one or more groups of physical pages of memory cells 308, and physical pages of memory cells 308 often include every other memory cell 308 commonly connected to a given access line 302. For example, memory cells 308 commonly connected to access line 302y and selectively connected to even data lines 204 (e.g., data lines 204₀, 204₂, 204₄, etc.) might be one physical page of memory cells 308 (e.g., even memory cells) while memory cells 308 commonly connected to access line 302_{Y} and selectively connected to odd data lines 204 (e.g., data lines 204₁, 204₃, 204₅, etc.) might be another physical page of memory cells 308 (e.g., odd memory cells). Although data lines 204₃-204₅ are not explicitly depicted in FIG. 2B, it is apparent from the figure that the data lines 204 of the array of memory cells 200B might be numbered consecutively from data line 204₀ to data line 204_{M}. Other groupings of memory cells 308 commonly connected to a given access line 302 might also define a physical page of memory cells 308. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation might be deemed a logical page of memory cells. A block of memory cells might include those memory cells that are configured to be erased together, such as all memory cells connected to access lines 302₀-302_{Y} (e.g., all NAND strings 306 sharing common access lines 302). Unless expressly distinguished, a reference to a page of memory cells herein refers to the memory cells of a logical page of memory cells.

Although the example of FIG. 2B is discussed in conjunction with NAND flash, the embodiments and concepts described herein are not limited to a particular array architecture or structure, and can include other structures and other architectures (e.g., AND arrays, NOR arrays, etc.).

FIG. 2C is another schematic of a portion of an array of memory cells 200C as could be used in a memory of the type described with reference to FIG. 1, e.g., as a portion of array of memory cells 103. Like numbered elements in FIG. 2C correspond to the description as provided with respect to FIGS. 2A and 2B. FIG. 2C provides additional detail of one example of a three-dimensional NAND memory array structure. The three-dimensional NAND memory array 200C might incorporate vertical structures which might include semiconductor pillars where a portion of a pillar might act as a channel region of the memory cells of NAND strings 206 and 306. The NAND strings 206 and 306 might be each selectively connected to a data line 204₀ to 204_{M} by a select transistor 212 and 312 (e.g., that might be drain select transistors, commonly referred to as select gate drain) and to a common source 216 by a select transistor 210 and 310 (e.g., that might be source select transistors, commonly referred to as select gate source), respectively. Multiple NAND strings 206 and 306 might be selectively connected to the same data line 204. Subsets of NAND strings 206 and 306 can be connected to their respective data lines 204 by biasing the select lines 215₀ to 215_{K} and 315 to selectively activate particular select transistors 212 and 312 each between a NAND string 206 and 306 and a data line 204, respectively. The select transistors 210 and 310 can be activated by biasing the select line 214₀ to 214_{K} and 314, respectively. Each access line 202 and 302 might be connected to multiple rows of memory cells of the memory array 200C. Rows of memory cells that are commonly connected to each other by a particular access line 202 or 302 might collectively be referred to as tiers.

The three-dimensional NAND memory array 200C might be formed over peripheral circuitry 226. The peripheral circuitry 226 might represent a variety of circuitry for accessing the memory array 200C. The peripheral circuitry 226 might include complementary circuit elements. For example, the peripheral circuitry 226 might include both n-channel and p-channel transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation remains as a matter of convenience.

The bias voltages applied to selected charge trap memory cells 208 might be higher than the bias voltages applied to selected ferroelectric memory cells 308 during access operations. For example, control logic (e.g., 116 of FIG. 1) might be configured to, during a program operation of a selected charge trap memory cell 208 of a first string 206 of series-connected charge trap memory cells, bias a gate 226 of the selected charge trap memory cell to a first voltage level. The control logic might be configured to, during a program operation of a selected ferroelectric memory cell 308 of a second string 306 of series-connected ferroelectric memory cells, bias a gate 336 of the selected ferroelectric memory cell to a second voltage level less than the first voltage level.

FIG. 2D is a further schematic of a portion of an array of memory cells 200D as could be used in a memory of the type described with reference to FIG. 1, e.g., as a portion of array of memory cells 103. Like numbered elements in FIG. 2D correspond to the description as provided with respect to FIGS. 2A and 2B. Array of memory cells 200D may include strings of series-connected memory cells (e.g., NAND strings) 206, access (e.g., word) lines 202, data (e.g., bit) lines 204, select lines 214 (e.g., source select lines), select lines 215 (e.g., drain select lines) and source 216 as depicted in FIG. 2A, and strings of series-connected memory cells (e.g., NAND strings) 306, access (e.g., word) lines 302, select lines 314 (e.g., source select lines), and select lines 315 (e.g., drain select lines) as depicted in FIG. 2B. A portion of the array of memory cells 200A may be a portion of the array of memory cells 200D, and a portion of the array of memory cells 200B may be another portion of the array of memory cells 200D, for example. FIG. 2D depicts groupings of NAND strings 206 and 306 into blocks of memory cells 250, e.g., blocks of memory cells 250₀ to 250_{L}. Blocks of memory cells 250 may be groupings of memory cells 208 or 308 that may be erased together in a single erase operation, sometimes referred to as erase blocks. Each block of memory cells 250 might include those NAND strings 206 and 306 commonly associated with a single select line 215 and 315, e.g., select line 215₀ and 315_{L}, respectively. The source 216 for the block of charge trap memory cells 250₀ might be a same source as the source 216 for the block of ferroelectric memory cells 250_{L}. For example, each block of memory cells 250₀ to 250_{L}, might be commonly selectively connected to the source 216. Access lines 202 and 302, select lines 214 and 314, and select lines 215 and 315 of one block of memory cells 250 may have no direct connection to access lines 202 and 302, select lines 214 and 314, and select lines 215 and 315, respectively, of any other block of memory cells of the blocks of memory cells 250₀ to 250_{L}.

The data lines 204₀ to 204_{M} may be connected (e.g., selectively connected) to a buffer portion 240, which might be a portion of a data buffer of the memory. The buffer portion 240 might correspond to a memory plane (e.g., the set of blocks of memory cells 250₀ to 250_{L}). The buffer portion 240 might include sense circuits (not shown in FIG. 2D) for sensing data values indicated on respective data lines 204.

While the blocks of memory cells 250 of FIG. 2D depict only one select line 215 and 315 per block of memory cells 250, the blocks of memory cells 250 might include those NAND strings 206 and 306 commonly associated with more than one select line 215 and 315, respectively. For example, select line 215₀ of block of memory cells 250₀ might correspond to the select line 215₀ of the memory array 200C of FIG. 2C, and the block of memory cells of the memory array 200D of FIG. 2D might further include those NAND strings 206 associated with select lines 215₁ to 215_{K} of FIG. 2C. In such blocks of memory cells 250 having NAND strings 206 associated with multiple select lines 215, those NAND strings 206 commonly associated with a single select line 215 might be referred to as a sub-block of memory cells. Each such sub-block of memory cells might be selectively connected to the buffer portion 240 responsive to its respective select line 215. Likewise, in such blocks of memory cells 250 having NAND strings 306 associated with multiple select lines 315, those NAND strings 306 commonly associated with a single select line 315 might be referred to as a sub-block of memory cells. Each such sub-block of memory cells might be selectively connected to the buffer portion 240 responsive to its respective select line 315.

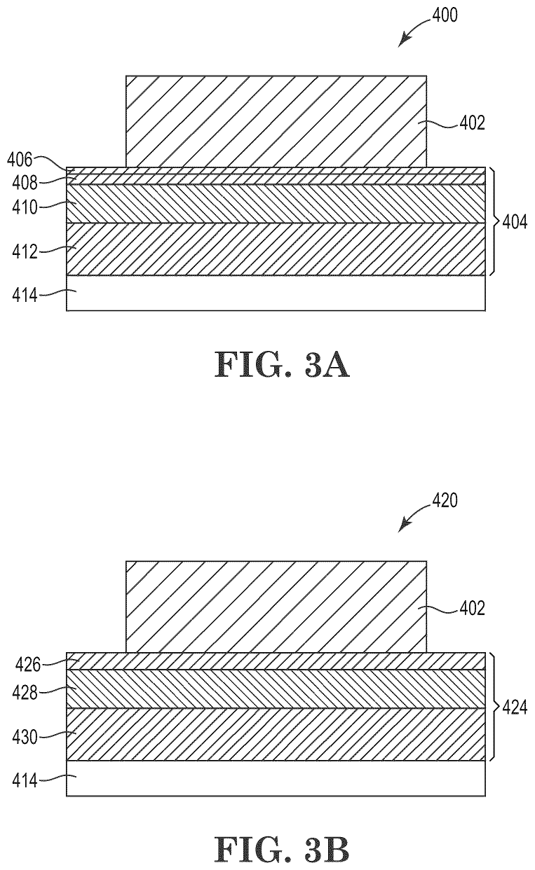

FIG. 3A is a cross-sectional view illustrating a structure 400 for a charge trap memory cell, which might provide a memory cell 208 of FIG. 2A, 2C, or 2D. The charge trap memory cell structure 400 might include a metal gate 402 (e.g., TiN), a gate stack 404 adjacent to the metal gate 402, and a channel region 414 (e.g., polysilicon) adjacent to the gate stack 404. The gate stack 404 might include an oxide layer 406 (e.g., AlO_{X}) adjacent to the metal gate 402, a blocking oxide layer 408 (e.g., SiO₂) adjacent to the oxide layer 406, a storage nitride layer 410 (e.g., SiaN₄) adjacent to the blocking oxide layer 408, and a tunnel oxide layer 412 (e.g., SiO₂) between the storage nitride layer 410 and the channel region 414. In some embodiments, the oxide layer 406 and the blocking oxide layer 408 might be combined into a single layer (e.g., SiO₂ and/or a high-k dielectric, such as AlOₓ).

FIG. 3B is a cross-sectional view illustrating a structure 420 for a ferroelectric memory cell, which might provide a memory cell 308 of FIG. 2B, 2C, or 2D. The ferroelectric memory cell structure might include a metal gate 402 (e.g., TiN), a gate stack 424, and a channel region 414 (e.g., polysilicon). The gate stack 424 might include a gate interfacial layer 426 (e.g., AlO_{X}) adjacent to the metal gate 402, a ferroelectric layer 428 (e.g., HfSiO_{X}) adjacent to the gate interfacial layer 426, and a channel interfacial layer 430 (e.g., SiO₂) between the ferroelectric layer 428 and the channel region 414.

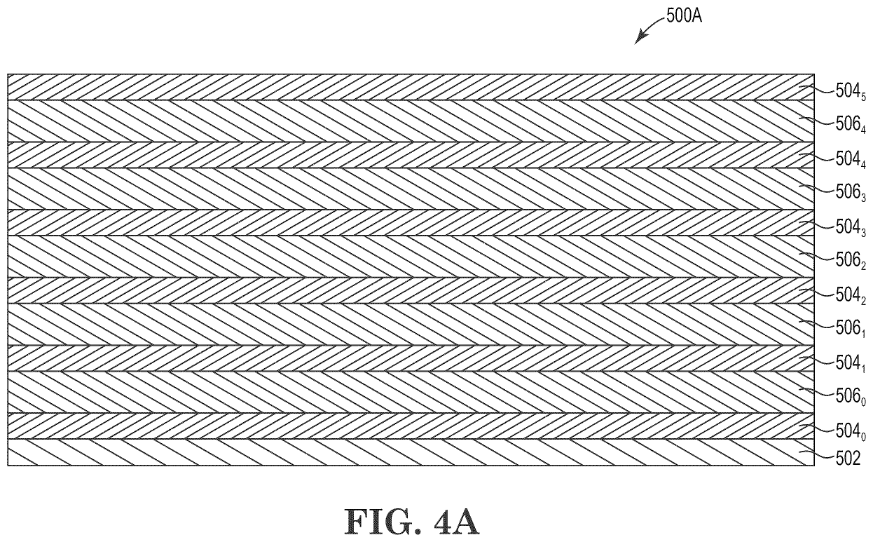

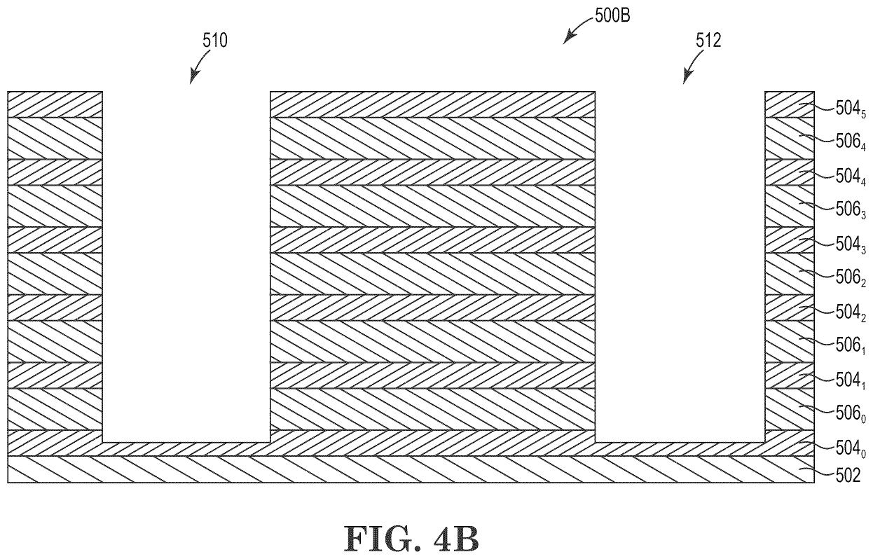

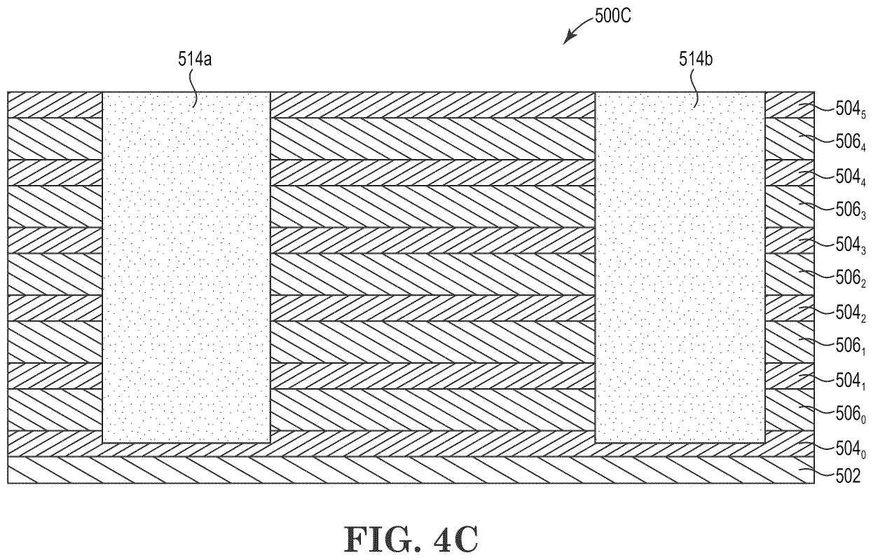

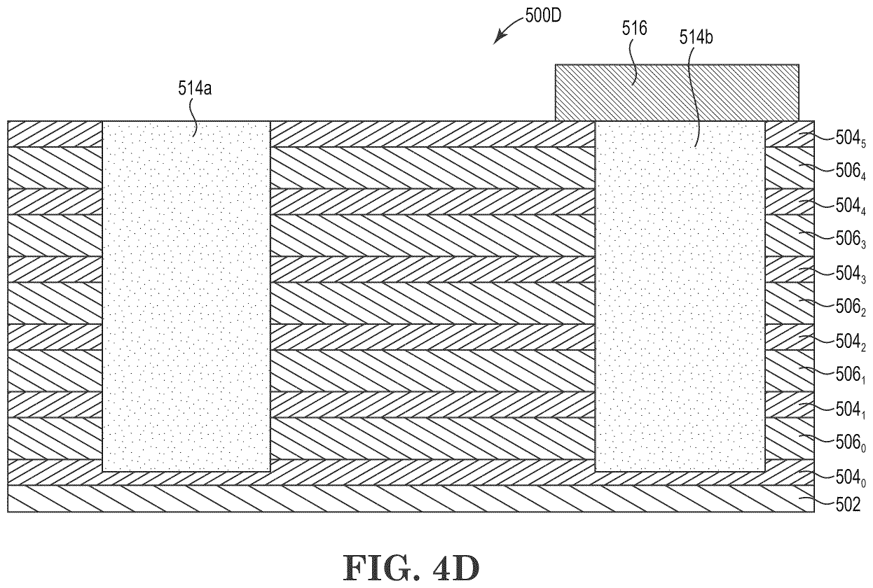

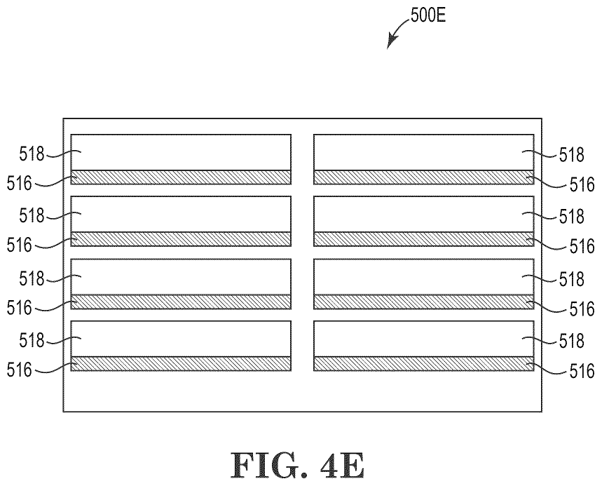

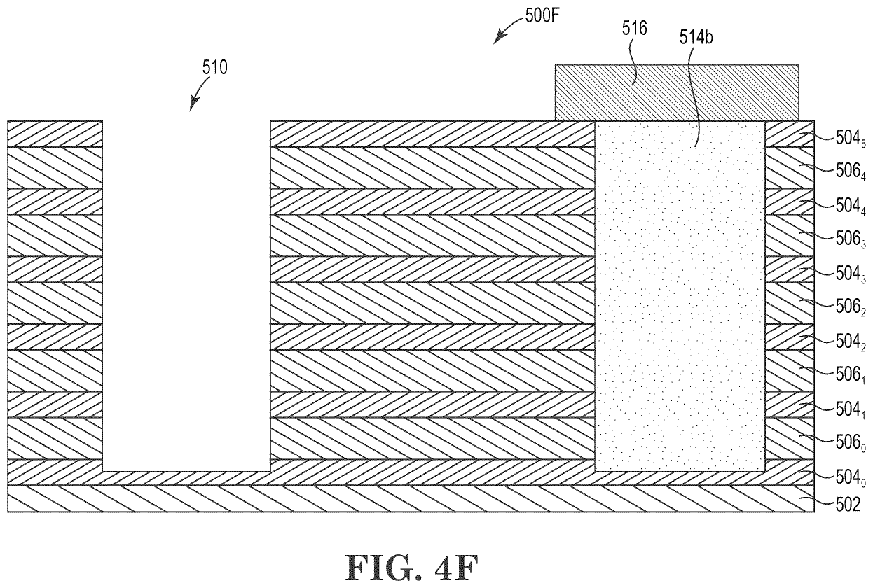

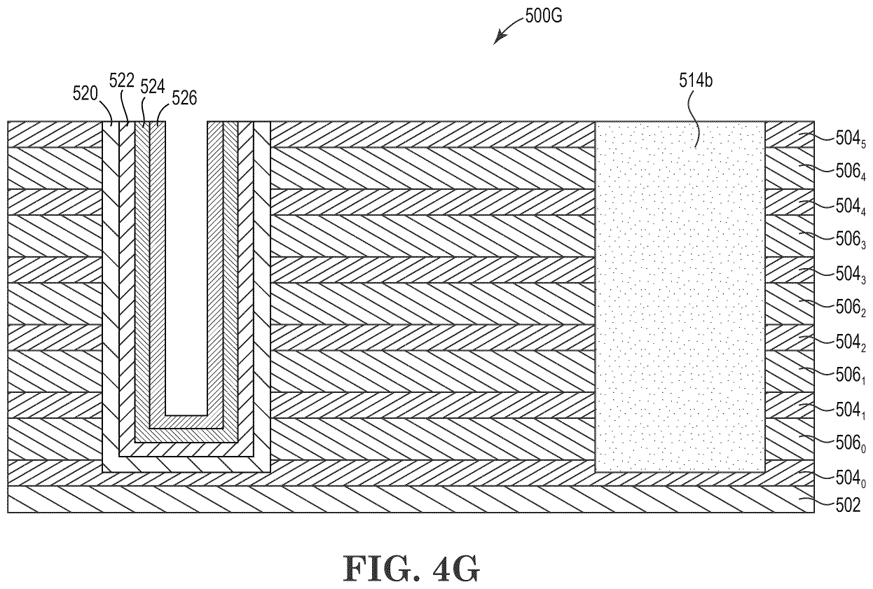

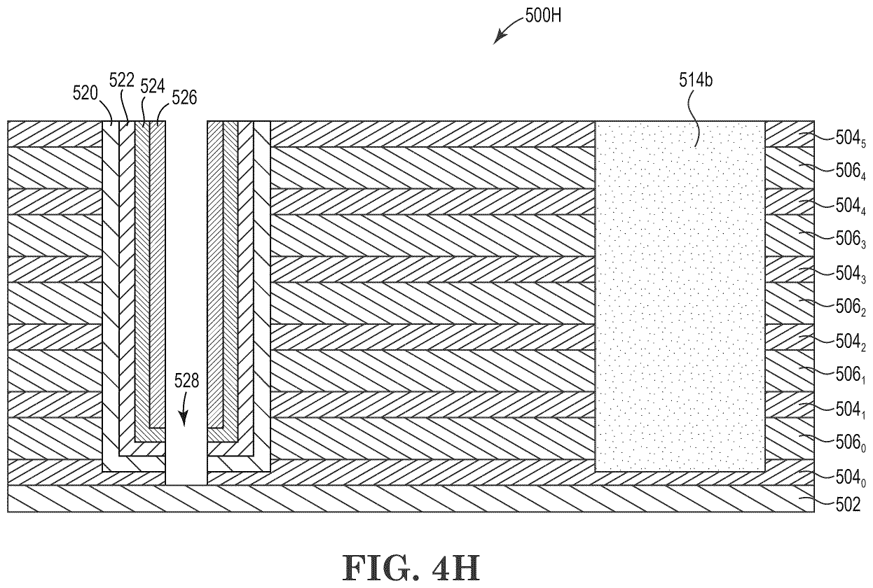

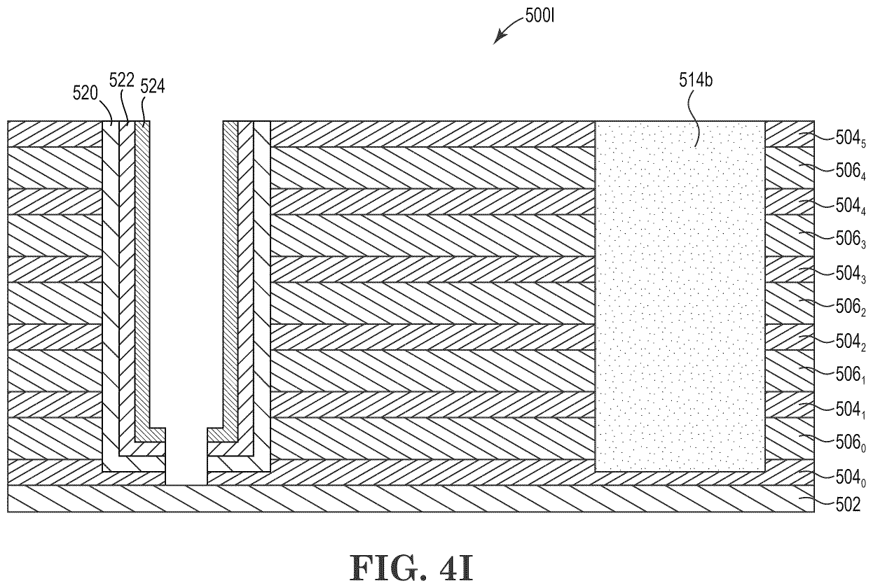

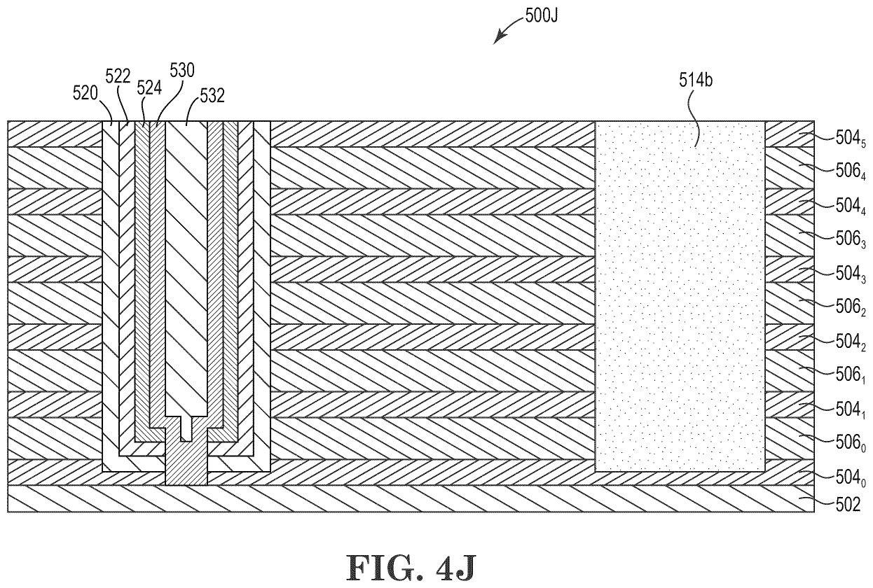

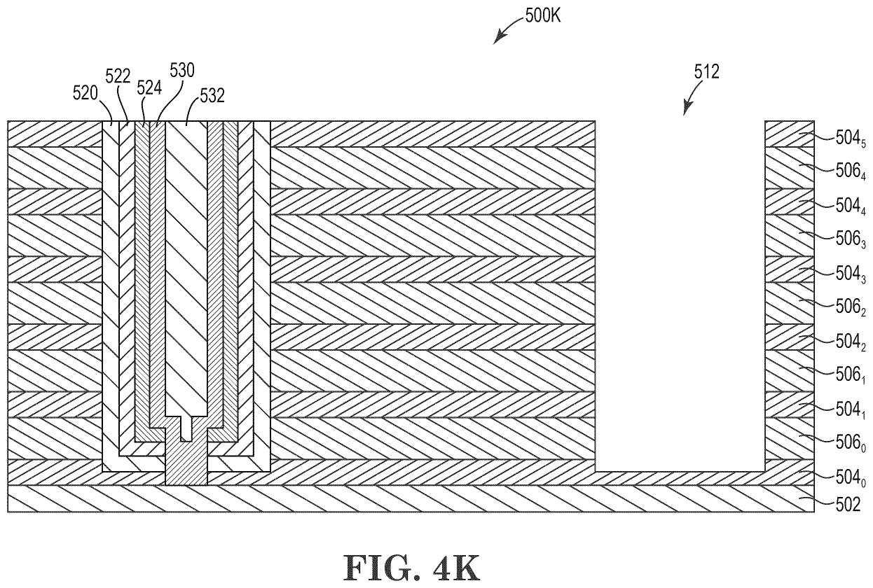

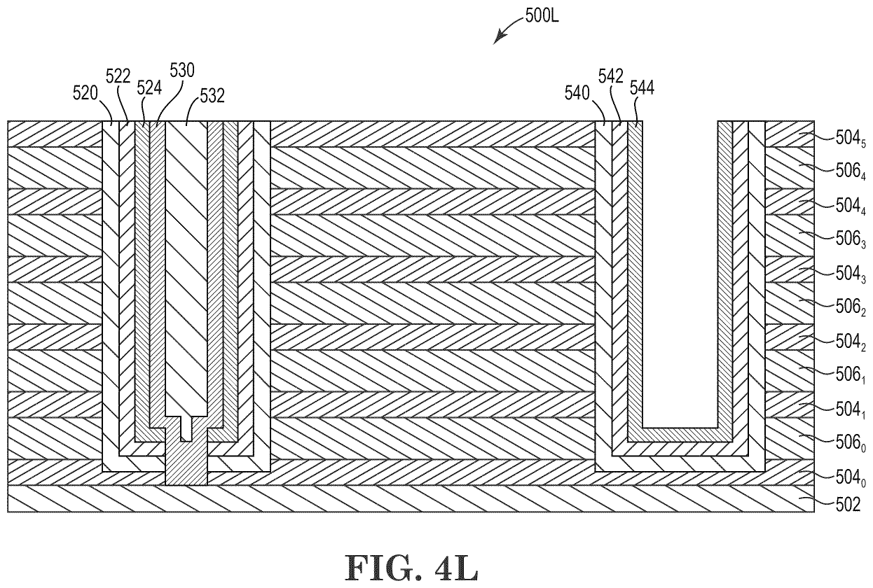

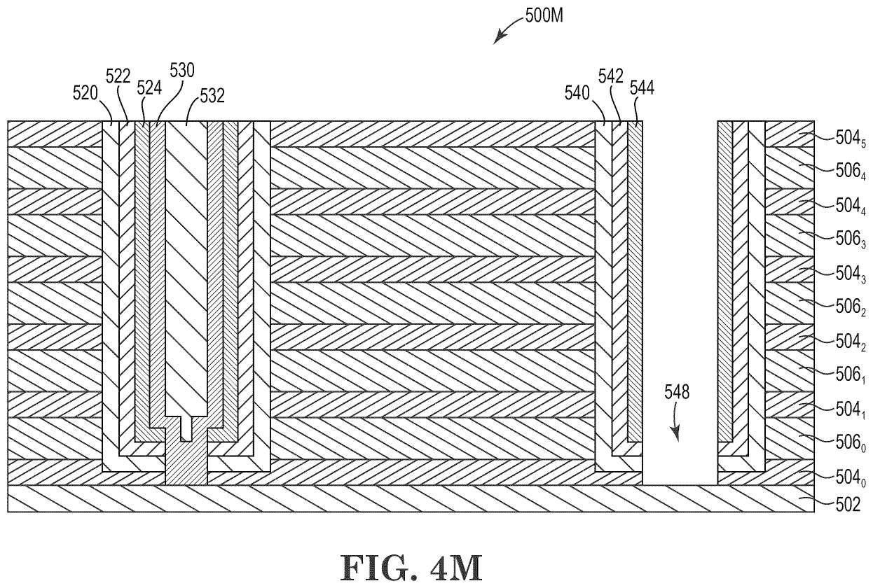

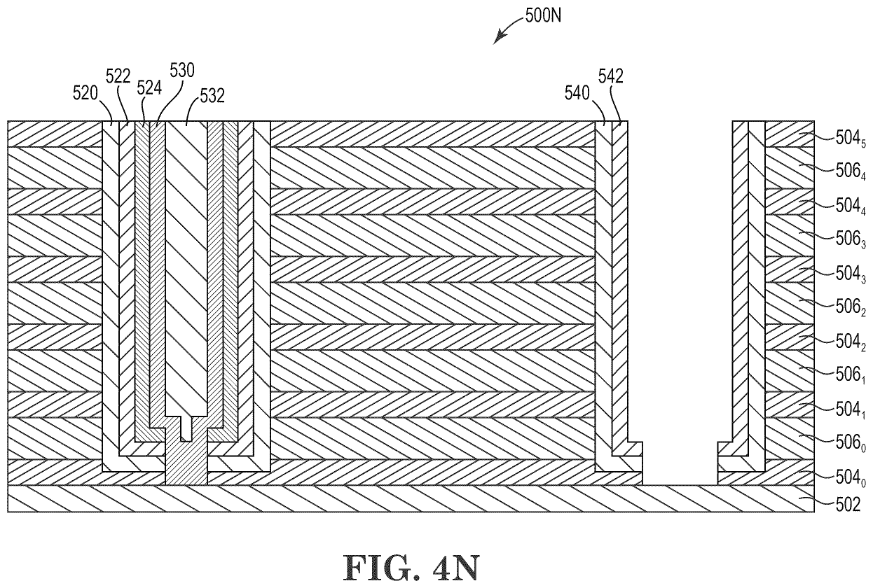

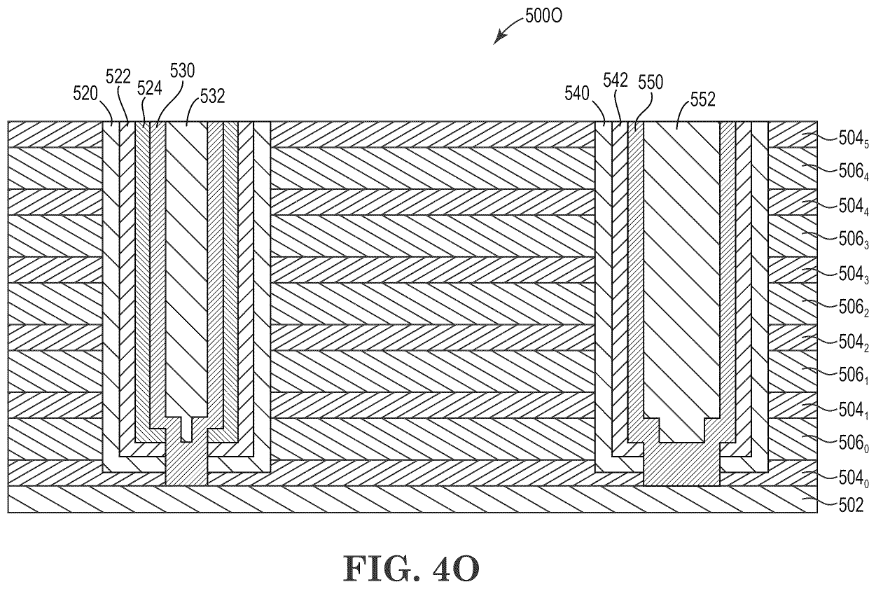

FIGS. 4A-40 illustrate a method for fabricating a memory array, such as memory array 103 of FIG. 1, 200C of FIG. 2C, or 200D of FIG. 2D, according to embodiments. As illustrated at 500A in FIG. 4A, a plurality of layers might be deposited on a source material layer 502. A tier oxide layer 504₀ might be deposited on the source material layer 502. A tier nitride layer 506₀ might be deposited on the tier oxide layer 504₀. A tier oxide layer 504₁ and a tier nitride layer 506₁ might be respectively deposited on the tier nitride layer 506₀. A tier oxide layer 504₂ and a tier nitride layer 506₂ might be respectively deposited on the tier nitride layer 506₁. A tier oxide layer 504₃ and a tier nitride layer 506₃ might be respectively deposited on the tier nitride layer 506₂. A tier oxide layer 504₄ and a tier nitride layer 506₄ might be respectively deposited on the tier nitride layer 506₃. A plurality of additional tier oxide layers (e.g., 504₅) and tier nitride layers (not shown) might be respectively deposited on the tier nitride layer 506₄. The number of tier oxide layers 504 and tier nitride layers 506 might be based on the number of transistors (e.g., memory cells and select gates) using structures 400 and 420 of FIGS. 3A and 3B, respectively.

As illustrated at 500B in FIG. 4B, layers 502, 504₀ to 504₅, and 506₀ to 5064 might be etched to form an opening as indicated at 510 for a pillar for an array (e.g., block) of charge trap memory cells (e.g., 208) and an opening 512 for a pillar for an array (e.g., block) of ferroelectric memory cells (e.g., 308), stopping in or below the tier oxide layer 504₀. As illustrated at 500C in FIG. 4C, the openings 510 and 512 might be filled with a sacrificial material 514a and 514b (e.g., polysilicon), respectively. As illustrated at 500D in FIG. 4D, the sacrificial material 514b for the pillar for a block of ferroelectric memory cells might be masked as indicated at 516 using a photoresist or other suitable mask material. As illustrated at 500E in the top view of FIG. 4E, multiple blocks of charge trap memory cells including corresponding pillars and multiple blocks of ferroelectric memory cells including corresponding pillars might be fabricated simultaneously, such that a mask 516 masks each portion where a block of ferroelectric memory cells are to be fabricated and each portion 518 indicates where charge trap memory cells are to be fabricated. Thus, each mask 516 in FIG. 4E might mask multiple openings 512 filled with sacrificial material 514b, and each portion 518 in FIG. 4E might include multiple openings 510 filled with sacrificial material 514a. As illustrated at 500F in FIG. 4F, the sacrificial material 514a is removed from the opening 510 for a pillar for an array of charge trap memory cells.

As illustrated at 500G in FIG. 4G, a blocking dielectric layer 520 (e.g., SiO₂ and/or a high-k dielectric, such as AlOx) might be deposited on the walls and floor of the opening 510. A storage layer 522 (e.g., Si₃N₄) might be deposited on the blocking dielectric layer 520 within the opening. A tunneling dielectric layer 524 (e.g., SiO₂, oxynitride, Si₃N₄, or a combination thereof) might be deposited on the storage layer 522 within the opening. A punch layer (e.g., polysilicon) 526 might be deposited on the tunneling dielectric layer 524 within the opening. As illustrated at 500H in FIG. 4H, a punch etch might be used to etch the punch layer 526, the tunneling dielectric layer 524, the storage layer 522, the blocking dielectric layer 520, and the tier oxide layer 504₀ at the bottom of the opening to expose the source material layer 502 as indicated at 528.

As illustrated at 500I in FIG. 4I, the punch layer 526 might be removed (e.g., via a wet etch). As illustrated at 500J in FIG. 4J, a channel material 530 (e.g., polysilicon) might be deposited within the opening on the tunneling dielectric layer 524 and on source material layer 502 to connect to the source material layer and to form a vertical channel region. A dielectric material 532 might be deposited on the channel material 530 to fill the opening.

As illustrated at 500K in FIG. 4K, the sacrificial polysilicon 514b might be removed from the opening 512 where a pillar for the block of charge trap memory cells is to be formed. As illustrated at 500L in FIG. 4L, a ferroelectric layer 540 (e.g., HfSiO₂) might be deposited on the walls and floor of the opening 512. A channel interfacial layer 542 (e.g., SiO₂) might be deposited on the ferroelectric layer 540 within the opening. A punch layer 544 (e.g., polysilicon) might be deposited on the channel interfacial layer 542 within the opening. As illustrated at 500M in FIG. 4M, a punch etch might be used to etch the punch layer 544, the channel interfacial layer 542, the ferroelectric layer 540, and the tier oxide layer 504₀ at the bottom of the opening to expose the source material layer 502 as indicated at 548.

As illustrated at 500N in FIG. 4N, the punch layer 544 might be removed (e.g., via a wet etch). As illustrated at 500O in FIG. 4O, a channel material 550 (e.g., polysilicon) might be deposited within the opening on the channel interfacial layer 542 and on source material layer 502 to connect to the source material layer and to form a vertical channel region. A dielectric material 552 might be deposited on the channel material 550 to fill the opening.

A replacement gate process and metal fill (not shown) might then be implemented as known in the art to complete the pillar structures and the portions of the array of memory cells 103 including an array of charge trap memory cells 104 and a block of ferroelectric memory cells 105. The layers 504₀ to 505₅ and 506₀ to 506₄ might be etched (not shown) to form openings as for a replacement gate process. The tier nitride layers 506₀ to 506₄ might be removed. A metal might be deposited to form gates where the tier nitride layers 506₀ to 506₄ were removed. The metal might be etched (e.g., via a dry and/or wet etch) to isolate the gates. A dielectric might be deposited to fill the openings. Contacts might be formed to the gates formed by the metal and data lines might be contacted to the vertical channel regions to complete the fabrication of the array of memory cells.

While FIGS. 4A-4O illustrate a punch flow process, in other embodiments, a lateral contact flow process or a backside source flow process might be used to fabricate the array of memory cells including charge trap memory cells and ferroelectric memory cells. In some embodiments, the replacement gate film deposition might be differentiated and not merely a pillar deposition. In some embodiments, different dielectric or metal workfunction deposition might be used.

Accordingly, a method for fabricating a memory array (e.g., 103) might include forming a first string 206 of series-connected charge trap memory cells 208 including a first vertical channel region (e.g., 532), where each charge trap memory cell of the first string of series-connected memory cells includes a first gate stack structure (e.g., 404 of FIG. 3A). The method might include forming a second string 306 of series-connected ferroelectric memory cells 308 adjacent to the first string of series-connected charge trap memory cells. The second string of series-connected ferroelectric memory cells includes a second vertical channel region (e.g., 552), and each ferroelectric memory cell of the second string of series-connected memory cells includes a second gate stack structure (e.g., 424 of FIG. 3B) different from the first gate stack structure.

### CONCLUSION

Although specific embodiments have been illustrated and described herein, it will be appreciated by those of ordinary skill in the art that any arrangement that is calculated to achieve the same purpose may be substituted for the specific embodiments shown. Many adaptations of the embodiments will be apparent to those of ordinary skill in the art. Accordingly, this application is intended to cover any adaptations or variations of the embodiments.

What is claimed is:

1. A memory device comprising:
an array of memory cells comprising charge trap memory cells and ferroelectric memory cells; and
control logic configured to access the array of memory cells.

2. The memory device of claim 1, wherein the array of memory cells comprises a first string of series-connected charge trap memory cells comprising a first vertical channel region, each charge trap memory cell of the first string of series-connected memory cells comprising a first gate stack structure, and
wherein the array of memory cells comprises a second string of series-connected ferroelectric memory cells comprising a second vertical channel region, each ferroelectric memory cell of the second string of series-connected memory cells comprising a second gate stack structure different from the first gate stack structure.

3. The memory device of claim 2, wherein the first gate stack structure comprises a metal gate layer, a blocking oxide layer, a storage nitride layer, and a tunnel oxide layer.

4. The memory device of claim 2, wherein the second gate stack structure comprises a metal gate layer, a gate interfacial layer, a ferroelectric layer, and a channel interfacial layer.

5. The memory device of claim 2, wherein the first string of series connected memory cells is connected between a data line and a common source, and
wherein the second string of series connected memory cells is connected between the data line and the common source.

6. The memory device of claim 1, further comprising:
first row decode circuitry to decode address signals for accessing the charge trap memory cells; and
second row decode circuitry to decode address signals for accessing the ferroelectric memory cells.

7. The memory device of claim 1, wherein the control logic is configured to, during a program operation of a selected charge trap memory cell of the first string of series-connected charge trap memory cells, bias a gate of the selected charge trap memory cell to a first voltage level; and
wherein the control logic is configured to, during a program operation of a selected ferroelectric memory cell of the second string of series-connected ferroelectric memory cells, bias a gate of the selected ferroelectric memory cell to a second voltage level less than the first voltage level.

8. The memory device of claim 1, wherein the ferroelectric memory cells comprise between 1 percent and 50 percent of the array of memory cells.

9. The memory device of claim 1, wherein the ferroelectric memory cells comprise a cache block of memory cells.

10. A three-dimensional NAND memory array comprising:
a first string of series-connected charge trap memory cells connected between a data line and a common source;
a first semiconductor pillar providing a channel region of the first string of series-connected charge trap memory cells;
a second string of series-connected ferroelectric memory cells connected between the data line and the common source; and
a second semiconductor pillar providing a channel region of the second string of series-connected ferroelectric memory cells.

11. The memory array of claim 10, further comprising:
a first select transistor connected between the data line and the first string of series-connected charge trap memory cells;
a second select transistor connected between the common source and the first string of series-connected charge trap memory cells;
a third select transistor connected between the data line and the second string of series-connected ferroelectric memory cells; and
a fourth select transistor connected between the common source and the second string of series-connected ferroelectric memory cells.

12. The memory array of claim 10, wherein each memory cell of the first string of series-connected charge trap memory cells comprises a first gate stack structure comprising a TiN gate layer, an AlOx blocking layer, a nitride storage layer, and a tunnel oxide layer.

13. The memory array of claim 10, wherein each memory cell of the second string of series-connected ferroelectric memory cells comprises a second gate stack structure comprising a TiN gate layer, an AlOx gate interfacial layer, a HfSiO_{X} ferroelectric layer, and a SiO₂ channel interfacial layer.

14. The memory array of claim 10, wherein the first semiconductor pillar and the second semiconductor pillar comprise polysilicon.

15. A method for fabricating a memory array, the method comprising:
forming a first string of series-connected charge trap memory cells comprising a first vertical channel region, each charge trap memory cell of the first string of series-connected memory cells comprising a first gate stack structure, and
forming a second string of series-connected ferroelectric memory cells adjacent to the first string of series-connected charge trap memory cells, the second string of series-connected ferroelectric memory cells comprising a second vertical channel region, each ferroelectric memory cell of the second string of series-connected memory cells comprising a second gate stack structure different from the first gate stack structure.

16. The method of claim 15, wherein forming the first string of series-connected charge trap memory cells and forming the second string of series connected ferroelectric memory cells comprises:
etching an oxide layer and nitride layer tier stack to form a first opening for the first string of series-connected charge trap memory cells and a second opening for the second string of series-connected ferroelectric memory cells;
filling the first opening and the second opening with a sacrificial material;
masking the second opening filled with the sacrificial material;
removing the sacrificial material from the first opening;
forming the first gate stack structure in the first opening for each memory cell of the first string of series-connected charge trap memory cells;
with the forming of the first gate stack structure in the first opening for each memory cell of the first string of series-connected charge trap memory cells complete, removing the sacrificial material from the second opening; and
forming the second gate stack structure in the second opening for each memory cell of the second string of series-connected ferroelectric memory cells.

17. The method of claim 16, wherein forming the first gate stack structure in the first opening for each memory cell of the first string of series-connected charge trap memory cells comprises:
depositing a blocking oxide layer on sidewalls of the first opening;
depositing a storage nitride layer on sidewalls of the blocking oxide layer;
depositing a tunnel oxide layer on sidewalls of the storage nitride layer; and
depositing a polysilicon layer on sidewalls of the tunnel oxide layer to form the first vertical channel region.

18. The method of claim 16, wherein forming the second gate stack structure in the second opening for each memory cell of the second string of series-connected ferroelectric memory cells comprises:
depositing a ferroelectric layer on sidewalls of the second opening;
depositing a channel interfacial layer on sidewalls of the ferroelectric layer; and
depositing a polysilicon layer on sidewalls of the channel interfacial layer to form the second vertical channel region.

19. The method of claim 15, further comprising:
contacting the first vertical channel region and the second vertical channel region to a common source.

20. The method of claim 15. further comprising:
contacting the first vertical channel region to a data line; and
contacting the second vertical channel region to the data line.
